(19) United States
(12) Patent Application Publication
(10) Pub. No.: US 2020/0068719 A1
(43) Pub. Date: Feb. 27, 2020

(54) COMPONENT MOUNTING DEVICE AND METHOD OF CONTROLLING THE SAME

(71) Applicant: KAWASAKI JUKOGYO KABUSHIKI KAISHA, Kobe-shi, Hyogo (JP)

(72) Inventors: Kenji BANDO, Nishinomiya-shi (JP); Shuhei KURAOKA, Akashi-shi (JP); Toshimitsu KIMURA, Kako-gun (JP); Kazunori HIRATA, Yao-shi (JP)

(73) Assignee: KAWASAKI JUKOGYO KABUSHIKI KAISHA, Kobe-shi, Hyogo (JP)

(21) Appl. No.: 16/465,519

(22) PCT Filed: Nov. 24, 2017
(86) PCT No.: PCT/JP2017/042246

§ 371 Date: May 30, 2019

(30) Foreign Application Priority Data
Nov. 30, 2016 (JP) 2016-232034

(51) Int. Cl. H05K 3/30

(52) U.S. Cl. CPC H05K 3/306; H05K 2203/0292; H05K 2203/167; H05K 2203/166

(57) ABSTRACT

A component mounting device includes: a holding body, pressing mechanism to press the holding body to move on a given route, position detector to detect a position of the holding body, and controller to control the mechanism. The route including: a start position of the holding body at which an insertion pin held by the body is separated from an insertion hole of a substrate, a first position range wherein the insertion pin is partially inserted, and a section position range wherein the insertion pin is fully inserted. When the holding body is pressed by a first pressing force to move on the given route from the start position toward the second position range, the controller controls the pressing mechanism to press the holding body by a pressing force different from the first pressing force, when the holding body stops at a position before or within the first position range.

### TECHNICAL FIELD

The present disclosure relates to a component mounting device and a method of controlling the component mounting device.

### BACKGROUND ART

Conventionally, lead terminals of an electronic component are inserted into insertion holes of an electronic circuit board or substrate to implement or mount the electronic component onto the electronic circuit board. If the lead terminal is bent, there may be an inconvenience that the lead terminal cannot be inserted into the insertion hole.

For this reason, for example, in a component inserting device of Patent Document 1, a component to be inserted is held by a chuck, and lead terminals are inserted into insertion holes of a printed circuit board. Here, when a poor insertion of the lead terminal into the insertion hole is detected, the lead terminal is inserted into the insertion hole, while the chuck is vibrated.

### REFERENCE DOCUMENT OF CONVENTIONAL ART

### Patent Document

[Patent Document 1] 22011-041403A

### DESCRIPTION OF THE DISCLOSURE

### Problems to be Solved by the Disclosure

However, the component inserting device of Patent Document 1 detects the poor insertion by a deformation of a flat spring provided between a robotic arm and the chuck. When the robotic arm inserts the lead terminals of the component to be inserted which is gripped by the chuck into the substrate, the device suspends the inserting operation if the poor insertion is detected by the flat spring provided between the robotic arm and the chuck being deformed. Then, the device inserts the lead terminals into the insertion holes, while vibrating the chuck.

Therefore, there is a problem that the conventional component inserting device cannot continuously perform the inserting operation of the component.

The present disclosure is made in view of such a situation, and one purpose thereof is to provide a component mounting device, and a method of controlling the same, which can successively perform an inserting operation of a component.

In order to solve the problem, a component mounting device according to one aspect of the present disclosure is a device configured to insert an insertion pin of a component having the insertion pin into an insertion hole of a substrate and mount the component to the substrate. The device includes a holding body configured to hold the component, a pressing mechanism configured to press the holding body to move the holding body on a given route, a position detector configured to detect a position of the holding body on the given route, and a controller configured to control the pressing mechanism based on the position of the holding body detected by the position detector. On the given route, a position of the holding body at which the insertion pin of the component held by the holding body is separated from the insertion hole of the substrate is a start position, a position range of the holding body at which the insertion pin of the component held by the holding body is partially inserted into the insertion hole of the substrate is a first position range, and a position of the holding body at which the insertion pin of the component held by the holding body is fully inserted into the insertion hole of the substrate is a second position range. In a case where the holding body is pressed by a first pressing force to move on the given route from the start position toward the second position range, the controller controls the pressing mechanism to press the holding body by a pressing force different from the first pressing force, when the holding body stops at a position before or within the first position range.

According to this configuration, as the first pressing force, a pressing force of the degree by which the component of which the insertion pin is deformed or has a barb part is partially inserted into the insertion hole and then is stopped, is selected. Thus, when the holding body is pressed by the first pressing force to move on the given route from the start position toward the second position range, if the held component has the deformed insertion pin or the barb part, the holding body stops within the first position range. In this case, by pressing the holding body with the pressing force larger than the first pressing force, the insertion pin of the component held by the holding body can completely inserted into the insertion hole. Further, when the tip end of the insertion pin contacts the surface of the substrate by a positioning error of the component, a comparatively large deformation of the insertion pin, etc., the holding body stops before the first position range. In this case, for example, by moving the component relatively to the substrate in a direction parallel to the substrate so as to grope or find out the insertion holes, while pressing the holding body by a pressing force smaller than the first pressing force, the tip end of the insertion pin is inserted into the insertion hole. Then the insertion pin of the component is completely inserted into the insertion hole. Alternatively, when the insertion pin is partially inserted into the insertion hole, since the holding body stops within the first position range, the holding body is pressed with the pressing force larger than the first pressing force as described above, and the insertion pin of the held component is completely inserted into the insertion hole.

Thus, in a state where the held component may not be inserted normally, since the holding body is stopped en route, and its handling operation is then performed, the inserting operation of the component can be performed continuously.

The controller may control the pressing mechanism to press the holding body by a second pressing force larger than the first pressing force, when the holding body stops within the first position range.

According to this configuration, the holding body which stops within the first position range due to the insertion pin of the component held by the holding body being deformed or having a barb part, is pressed with the second pressing force larger than the first pressing force and, thus, the insertion pin of the held component is completely inserted into the insertion hole.

The component mounting device may further include a groping mechanism configured to perform a groping operation in which the component held by the holding body is relatively moved with respect to the substrate in a direction parallel to the substrate so that the component gropes the insertion hole of the substrate. When the holding body stops before the first position range, the controller may control the groping mechanism to perform the groping operation, while controlling the pressing mechanism to press the holding body by a third pressing force smaller than the first pressing three.

According to this configuration, even if the tip end of the insertion pin contacts the surface of the substrate by a positioning error of the component, a comparatively large deformation of the insertion pin, etc., the groping operation is performed by the third pressing force which is smaller than the first pressing force so that the tip end of the insertion pin can be inserted into the insertion hole. Then the insertion pin of the component is completely inserted into the insertion hole. Alternatively, when the insertion pin is partially inserted into the insertion hole, since the holding body stops within the first position range, the holding body is pressed with the second pressing force larger than the first pressing force so that the insertion pin of the held component is completely inserted into the insertion hole.

The controller may control the groping mechanism so that a locus of the holding body draws a plurality of parallel line groups within a given area, when seen in the pressing direction of the pressing mechanism.

According to this configuration, by suitably reducing the interval of the plurality of parallel lines, since the holding body can be moved so as to perform a high-density scan of the given area on the surface of the substrate, the tip end of the insertion pin of the component can be inserted into the insertion hole with high probability.

The position detector may successively detect the position of the holding body on the given route.

According to this configuration, the controller can suitably determine where the holding body locates within the first position range and the second position range.

A position of the holding body at which the holding body that does not hold the component contacts the substrate may be a third position range. In a case where the holding body is pressed by the first pressing force to move on the given route from the start position toward the second position range, the controller may output an error signal when the holding body stops within the third position range.

According to this configuration, the abnormal of the holding body not holding the component can be detected.

A method of controlling a component mounting device according to another aspect of the present disclosure is a method of controlling a component mounting device. The device inserts an insertion pin of a component having the insertion pin into an insertion hole of a substrate and mounts the component to the substrate. The device includes a pressing mechanism configured to press a holding body configured to hold the component to move the holding body on a given route, a position detector configured to detect a position of the holding body on the given route, and a controller configured to control the pressing mechanism based on the position of the holding body detected by the position detector. On the given route, a position of the holding body at which the insertion pin of the component held by the holding body is separated from the insertion hole of the substrate is a start position, a position range of the holding body at which the insertion pin of the component held by the holding body is partially inserted into the insertion hole of the substrate is a first position range, and a position of the holding body at which the insertion pin of the component held by the holding body is fully inserted into the insertion hole of the substrate is a second position range. In a case where the holding body is pressed by a first pressing force to move the holding body on the given route from the start position toward the second position range, the controller controls the pressing mechanism to press the holding body by a pressing force different from the first pressing force, when the holding body stops at a position before or within the first position range.

According to this configuration, in the state where the held component may not be inserted normally, since the holding body is stopped en route, and its handling operation is then performed, the inserting operation of the component can be performed continuously.

### Effect of the Disclosure

The present disclosure has an effect to provide the component mounting device and the method of controlling the same, which can continuously perform the inserting operation of the component.

### BRIEF DESCRIPTION OF DRAWINGS

FIG. 1 is a front view schematically illustrating an entire structure of one example of a robot to which a component mounting device according to Embodiment 1 is applied.

FIG. 2 is a perspective view illustrating structures and operation of hands of the robot in FIG. 1.

FIG. 3 is a schematic view schematically illustrating a structure of a substantial part of the component mounting device in FIG. 1.

FIG. 4 is a functional block diagram schematically illustrating a configuration of a control device of the robot in FIG. 1.

FIG. 5a is a view illustrating operation of the substantial part of the component mounting device in FIG. 1, and is a view illustrating measurement of the height of a substrate.

FIG. 5b is a view illustrating the operation of the substantial part of the component mounting device in FIG. 1, and is a view illustrating a teaching position of a component insertion of the robot.

FIG. 5c is a view illustrating the operation of the substantial part of the component mounting device in FIG. 1, and is a view illustrating a case where a holding body does not hold a component.

FIG. 5d is a view illustrating the operation of the substantial part of the component mounting device in FIG. 1, and is a view illustrating a case where insertion pins of the component is normally inserted into the insertion holes of the substrate.

FIG. 5e is a view illustrating the operation of the substantial part of the component mounting device in FIG. 1, and is a view illustrating a case where the insertion pins of the component are not inserted into the insertion holes of the substrate.

FIG. 5f is a view illustrating the operation of the substantial part of the component mounting device in FIG. 1, and is a view illustrating a groping operation.

FIG. 5g is a view illustrating the operation of the substantial part of the component mounting device in FIG. 1, and is a view illustrating a case where the insertion pins are partially inserted into the insertion holes of the substrate, as a result of the groping operation.

FIG. 5h is a view illustrating the operation of the substantial part of the component mounting device in FIG. 1, and is a view illustrating a case where the component is pushed in until the insertion pins are fully inserted into the insertion holes, after the insertion pins are partially inserted into the insertion holes of the substrate.

FIG. 6 is a flowchart illustrating the outline of one example of a component inserting operation executed by the control device of the robot in FIG. 1.

FIG. 7 is a flowchart illustrating concrete processes of one example of the component inserting operation executed by the control device of the robot in FIG. 1.

FIG. 8 is a schematic view illustrating loci of the holding body during the groping operation.

FIG. 9 is a schematic view illustrating other loci of the holding body during the groping operation.

FIG. 10 is a schematic view illustrating structures of the component having the insertion pins.

### MODES FOR CARRYING OUT THE DISCLOSURE

Hereinafter, one embodiment of the present disclosure will be described with reference to the drawings. Note that, in the following description, the same reference characters are assigned to the same or corresponding elements throughout the drawings to omit redundant description. Moreover, the drawings illustrate each element schematically, in order to facilitate understandings and, thus, the shape and scale may not be accurately indicated. Further, a direction in which a pair of arms extend is referred to as a “left-and-right direction,” a direction parallel to an axial center of a base shaft is referred to as an “up-and-down direction,” and a direction perpendicular to the left-and-right direction and the up-and-down direction is referred to as a “front-and-rear direction.”

### Embodiment 1

A component mounting device 10 according to this embodiment is a device which inserts insertion pins of a component into insertion holes of a substrate to mount the component onto the substrate. The term “component” as used herein refers to an electronic component, electric component, a mechanical component, etc., having pin(s) to be inserted into insertion hole(s) of the substrate. The term “insertion pin” as used herein means “a pin-shaped protrusion of the component” to be inserted into the insertion hole of the substrate. The “insertion pin” may include a lead (lead wire) or a lead terminal of the electronic component or electric component, a fixture pin of the mechanical component. The term “substrate” as used herein means a board, a panel, etc. to which the component is mounted. The “substrate” may include an electronic circuit board, an electric circuit hoard, a substrate for solar panels, a substrate for display panels. Below, a form in which the electronic component is mounted onto the electronic circuit board is illustrated.

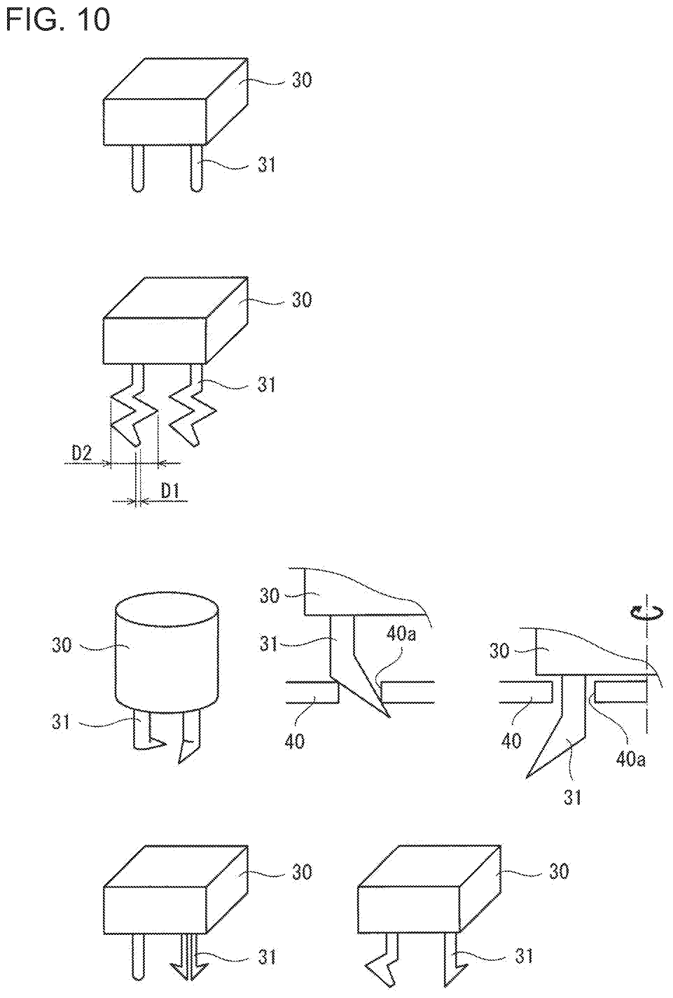

First, a concrete mode of the insertion pins of the component is illustrated. FIG. 10 is a schematic view illustrating structures of the component having the insertion pins.

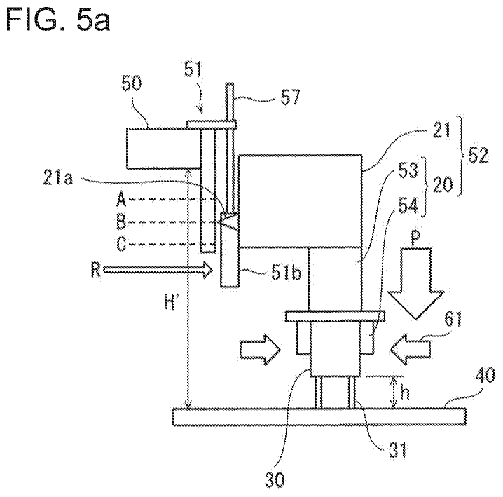

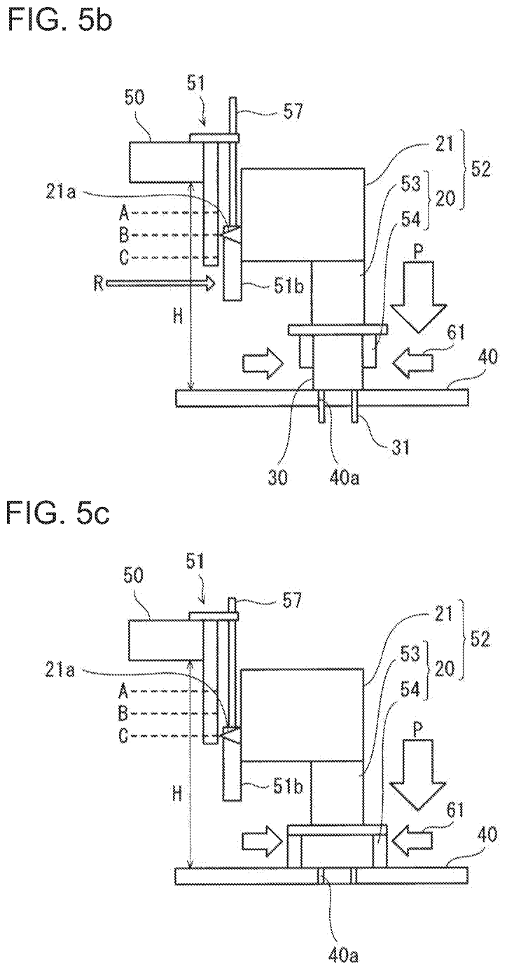

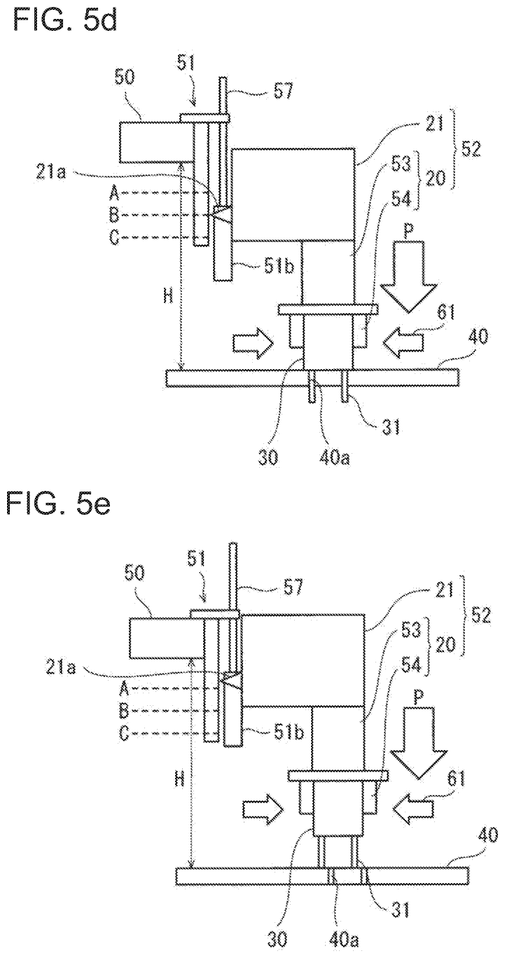

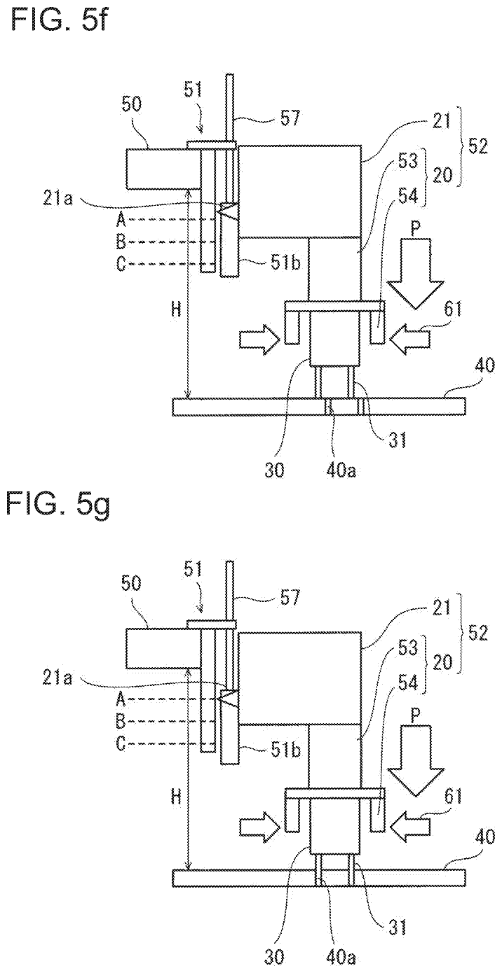

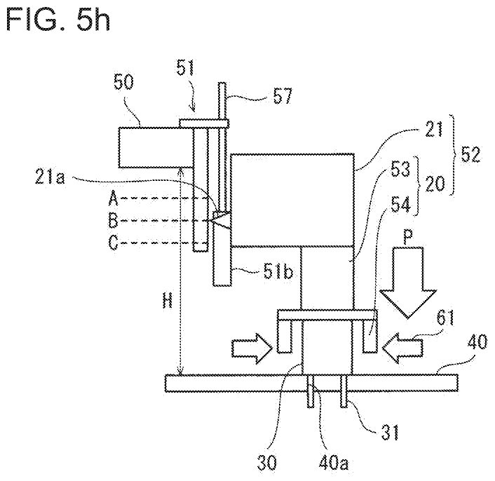

A component 30 having straight insertion pins 31 is illustrated in a first row of FIG. 10. In the case of such a component 30, the component 30 is mounted onto a substrate 40 by its own weight or a small pressing force (see FIG. 5d). In this case, the component 30 is not fixed to the substrate.

A component 30 having insertion pins 31 where bending parts are formed is illustrated in the second row of FIG. 10. In the case of such a component 30, since a dimension Di at a tip end of each insertion pin 31 is smaller than a diameter of each insertion hole 40a (see FIG. 5g), and a dimension D2 of the bending part of each insertion pin 31 is larger than the diameter of the insertion hole 40a, the component 30 can be mounted onto the substrate 40 (see FIG. 5h) by pressing the component 30 against the substrate 40 in a state where the tip ends of the insertion pins 31 are inserted in the insertion holes 40a. In this case, the component 30 is difficult to be pulled out from the substrate.

A component 30 having insertion pins 31 where hooks extending obliquely downward are formed in tip-end parts is illustrated in a third row of FIG. 10. In the case of such a component 30, the component 30 is mounted onto the substrate 40 by first inserting the tip ends of the insertion pins 31 into the insertion holes 40a, then turning the component 30 around its center axis, while pressing the component 30 against the substrate 40 (refer to description of Step S2D described later). In this case, the component 30 is locked to the substrate 40.

A component 30 having insertion pins 31 where a barb part or a bending part is formed to a tip-end part is illustrated in a fourth row of FIG. 10. In the case of such a component 30, the component 30 is mounted onto the substrate 40 by first inserting the tip ends of the insertion pins 31 into the insertion holes 40a, and then pressing the component 30 against the substrate 40 (see FIG. 5h). In this case, the component 30 is locked to the substrate 40.

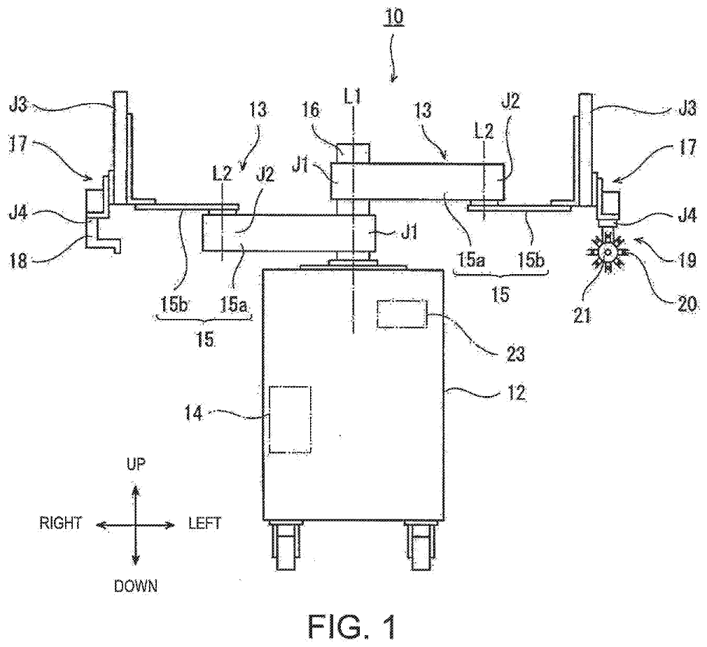

Next, a case where the component mounting device 10 according to the present disclosure is applied to a robot 11 illustrated in FIGS. 1 to 3 is described. Note that the component mounting device 10 is not limited to the application to the robot 11. For example, the component mounting device 10 may be a moving mechanism provided with a table which is movable in X, Y, and Z directions. Moreover, although a horizontal articulated dual-arm robot is described as the robot 11, other robots, such as a horizontal articulated and/or a vertical articulated robot, may also be adopted.

As illustrated in FIG. 1, the robot 11 includes a carriage 12, a pair of robotic arms (hereinafter, may simply be referred to as the “arms”) 13 supported by the carriage 12, and a control device 14 accommodated in the carriage 12. Each arm 13 is a horizontal articulated robotic arm, and is provided with an arm part 15, a wrist part 17, and an end effector (may also be referred to as the “hand”) 18 or 19.

The arm part 15 functions as a conveying part which conveys the component onto the substrate, and a groping mechanism which causes the component to perform a groping operation. In this example, the arm part 15 is comprised of a first link 15a and a second link 15b. Note that the left and right arms 13 have substantially the same structure except for the end effectors 18 and 19, and the left and right end effectors 18 and 19 may have the same or different structures. Moreover, the left and right arms 13 can operate independently or collaboratively.

The first link 15a of the arm part 15 is coupled to a base shaft 16 fixed to an upper surface of the carriage 12 via a rotary joint, and is rotatable about a rotation axis L1 passing through an axial center of the base shaft 16. The second link 15b is coupled to a tip end of the first link 15a via a rotary joint, and is rotatable about a rotation axis L2 defined at a tip end of the first link 15a. The wrist part 17 is coupled to a tip end of the second link 15b via a linear-motion joint, and is elevatable with respect to the second link 15b.

The end effectors 18 and 19 are each coupled to the wrist part 17 via a rotary joint and rotatable about a rotation axis. The end effectors 18 and 19 are each attached to the rotary joint via an attachment member 50.

Each arm 13 having the above structure has joint axes J1-J4 corresponding to the respective joints. The arm 13 is provided, corresponding to the joint axes J1-J4, with servo motors (not illustrated) for driving the respective joints, encoders (not illustrated) which detect rotational angles of the servo motors, etc. The rotation axes L1 of the first links 15a of the two arms 13 are located on the same straight line, and the first link 15a of one of the arms 13 and the first link 15a of the other arm 13 are provided with a height difference therebetween.

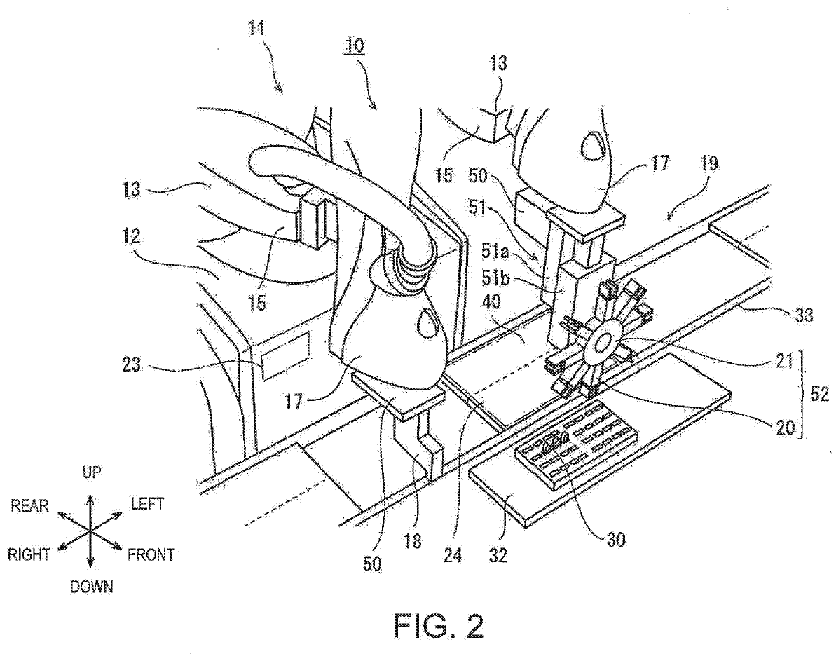

As illustrated in FIG. 2, the right end effector 18 is comprised of a transferring part (hand) which transports the substrate. Moreover, the left end effector 19 constitutes a substantial part of the component mounting device. The left end effector 19 has gripper parts 20 each of which grips the component 30, and may further have a rotary part 21 which moves the gripper parts 20 in the up-and-down direction while rotating the gripper parts 20. In this case, the gripper parts 20 and the rotary part 21 constitute a holding body 52 which holds the component 30. Note that, although only the left end effector 19 has the gripper parts 20, at least one of the right end effector 18 and the left end effector 19 may have the gripper parts 20. If both the right end effector 18 and the left end effector 19 have the gripper parts 20, one of the gripper parts 20 may differ in the shape from the other.

In this embodiment, the rotary part 21 is a circular plate body. The center axis of the rotary part 21 extends in a direction perpendicular to the joint axis J4 of the wrist part 17. A rotating shaft of the rotary part 21 is provided with a servo motor for driving the rotating shaft (not illustrated), an encoder (not illustrated) which detects a rotational angle of the servo motor, etc. Thus, the rotary part 21 rotates in the clockwise direction or the counterclockwise direction about the center axis, and stops at a rotational position where one of the gripper parts 20 is oriented in a direction parallel to the joint axis J4 of the wrist part 17, and oriented downwardly (hereinafter, referred to as the “inserting position”).

In this embodiment, the rotary part 21 is provided with, for example, eight gripper parts 20. The gripper parts 20 may have the same shape, or may have different shapes according to the shape of the component 30. The eight gripper parts 20 are disposed on the outer circumference of the rotary part 21 so that they are separated from each other in the circumferential direction by the central angle of 45 degrees.

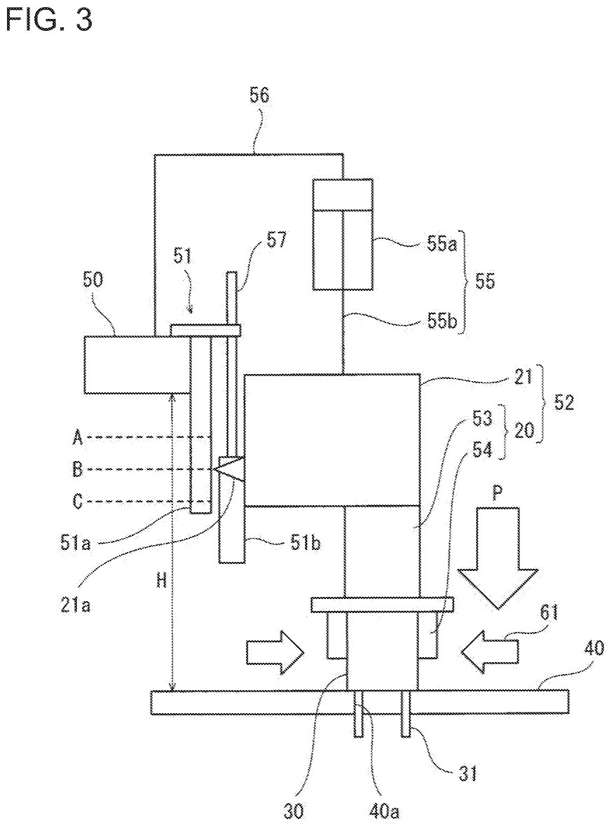

in order to facilitate description, only one gripper part 20 at the inserting position is illustrated in FIG. 3. Moreover, only a portion of the entire substrate 40 located near the gripper part 20 is illustrated. The gripper part 20 may be configured to grip the component 30. As illustrated in FIG. 3, in this embodiment, each gripper part 20 includes a pair of gripper members 54 each having a pawl shape, and a gripper member actuator 53 which drives the pair of gripper members 54. The pair of gripper members 54 constitutes a chuck. The gripper member actuator 53 is, for example, an air cylinder. Each gripper part 20 is formed in a pillar shape as a whole, and the gripper parts 20 are provided so as to extend radially outward from the rotary part 21. For example, the gripper member actuator 53 is disposed on the outer circumference of the rotary part 21, and the pair of gripper members 54 (chuck) disposed at a tip end of the gripper member actuator 53. The pair of gripper members 54 is provided so as to be slidable in a direction perpendicular to the radial direction of the rotary part 21, and is driven by the gripper member actuator 53 so as to pinch the component 30 and release the component 30. The reference character “61” indicates a pinching operation of the gripper part 20. The sliding direction of the pair of gripper members 54 may be any direction, as long as it is a direction perpendicular to the radial direction of the rotary part 21, and it is the circumferential direction (a tangent direction) of the rotary part 21. Note that, in FIG. 3, in order to facilitate description of an inserting process of the component 30, the sliding direction of the pair of gripper members 54 is drawn as if it is the axial direction of the rotary part 21. Note that, the gripper parts 20 may be, for example, a suction pad which sucks the component 30 with a negative pressure, or an electromagnet which attracts the component 30 containing magnetic material.

The rotary part 21 is attached to the attachment member 50 via a slide mechanism 51. For example, as illustrated in FIG. 2, the slide mechanism 51 includes a stationary body 51a having a linear guide part, and a movable body 51b which engages with the guide part and is slidable along the guide part. A sliding direction of the movable body 51b is a direction parallel to the joint axis J4 (the rotation axis of the rotary joint) of the wrist part 17.

Referring to FIG. 3, the stationary body 51a of the slide mechanism 51 is fixed to the attachment member 50, and the rotary part 21 is fixed to the movable body 51b of the slide mechanism 51. The movable body 51b reciprocates in its sliding direction by a pressing mechanism 55 fixed to the attachment member 50. For example, the pressing mechanism 55 is comprised of an air cylinder. A cylinder 55a of the air cylinder is fixed to the attachment member 50 via an attachment member 56, and a tip end of a piston rod 55b of the air cylinder is fixed to the rotary part 21. Thus, when the piston rod 55b of the air cylinder deploys and retracts, the rotary part 21, i.e., the holding body 52 approaches and separates from the substrate 40. Therefore, when the piston rod 55b of the air cylinder deploys, the holding body 52 is pressed. The reference character “P” represents this pressing force. Moreover, a path along which the holding body 52 approaches and separates from the substrate 40 is a route (hereinafter, referred to as the “given route”) along which the insertion pins 31 of the component 30 are inserted into the insertion holes 41a of the substrate 40. Moreover, a direction from a base end of the gripper part 20 which stops at the inserting position to the tip end is a pressing direction. Here, although the given route extends in the up-and-down direction and the pressing direction is a downward direction, the extending direction of the given route and the pressing direction may be arbitrary.

A position detector 57 which detects the position of the holding body 52 on the given route is provided to the left end effector 19. The position detector 57 is comprised of, for example, a linear scale. If the linear scale is used, the position of the holding body 52 on the given route can successively be detected. Of course, other position detectors may also be used. For example, three position sensors (e.g., magnets and Hall devices) which detect center positions of the first to third position ranges A-C may be provided to the slide mechanism 51 or the air cylinder (55), and the positions detected by the respective position sensors may be expanded to a given position range by using software.

A reference point 21a is set (defined) to the holding body 52. The reference point 21a is a position which represents the holding body 52. Below, “the position of the holding body” means “the position of the reference point 21a.” For example, the reference point 21a is set to the rotary part 21. Note that the reference point may be set anywhere as long as it is on the holding body 52. On the given route, a position of the holding body 52 at which the insertion pins 31 of the component 30 held by the holding body 52 are separated from the insertion holes 41a of the substrate 40 is set (defined) as a start position (not illustrated), a position range of the holding body 52 within which the insertion pins 31 of the component 30 held by the holding body 52 are partially inserted into the insertion holes 41a of the substrate 40 is set (defined) as the first position range A, a position of the holding body 52 at which the insertion pins 31 of the component 30 held by the holding body 52 are fully inserted into the insertion holes 40a of the substrate 40 is set (defined) as the second position range B, and a position of the holding body 52 at which the holding body 52 which does not hold the component 30 contacts the substrate 40 is set (defined) as the third position range C. The start position and the first to third position ranges A-C are associated with the position scale of the position detector 57. Therefore, the start position and the second to third position ranges A-C correspond to relative positions of the movable body 51b with respect to the stationary body 51 a in the slide mechanism 51. In this embodiment, the given route, the start position, and the first to third position ranges A-C are defined by a coordinate system of the left end effector 19. Therefore, even if the left end effector 19 moves according to the spatial positions of the insertion holes 40a of the substrate 40 which are insertion targets, the coordinates of the given route, the start position, and the first to third position ranges A-C do not change for the control. Thus, the control for the component insertion becomes simple. Of course, the coordinates of the given route, the start position, and the first to third position ranges A-C may be defined by a reference coordinates of the robot 11.

The center positions of the first to third position ranges A-C are determined based on, for example, the dimensions of the slide mechanism 51, the holding body 52, and the component 30, respectively. The first position range A is determined based on, for example, the positioning accuracy of the arm of the robot 11, the dimensional tolerance of the holding body , the dimensional tolerance of the component 30, the thickness of the substrate 40. The second position range B and the third position range C are determined based on, for example, the positioning accuracy of the arm of the robot 11, the dimensional tolerance of the holding body 52, the dimensional tolerance of the component 30. That is, the first to third position ranges A-C are determined so as to be able to detect a stop of the holding body 52 by using the position detector 57, even if the actually stopped position of the holding body 52 varies due to the positioning accuracy and the dimensional tolerance which are described above.

Moreover, the height of the surface of the substrate 40 with respect to a lower surface of the attachment member 50 is set (defined) as a substrate height H. The setup of the substrate height H, the reference point 21a, the start position, and the first to third position ranges A-C are performed by storing these values in a memory 14b of the control device 14.

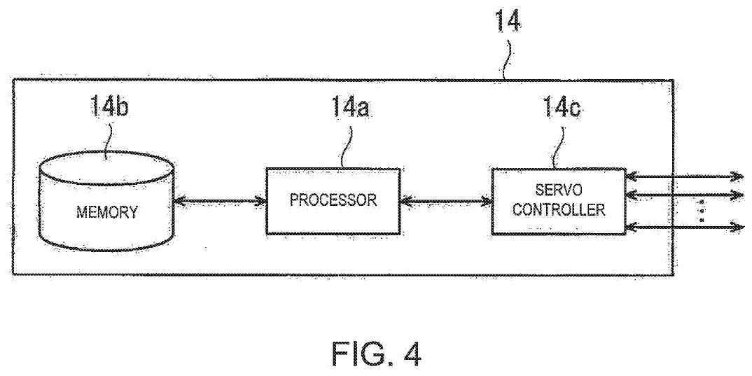

As illustrated in FIG. 4, the control device 14 includes a processor 14a, such as a CPU, the memory 14b, such as a ROM and/or RAM, and a servo controller 14c. The control device 14 is a robot controller provided with a computer, such as a microcontroller. Note that the control device 14 may be comprised of a single control device 14 which carries out a centralized control, or may be comprised of a plurality of control devices 14 which collaboratively carry out a distributed control.

The memory 14b stores information on a basic program as the robot controller, various fixed data, etc. The processor 14a controls various operations of the robot 11 by reading and executing software, such as the basic program stored in the memory 14b. For example, regarding the operation of the arm of the robot 11, the processor 14a generates a control command for the robot 11, and then outputs it to the servo controller 14c. The servo controller 14c is configured to control the drive of the servo motors corresponding to the joint axes J1-J4 of each arm 13 of the robot 11 based on the control commands generated by the processor 14a.

Moreover, the control device 14 controls the operation of the left end effector 19. For example, the control device 14 controls operation of the pressing mechanism 55 and the gripper member actuator 53 of the left end effector 19. Therefore, the control device 14 functions as a controller for the component mounting device while functioning as a controller which controls general operations of the robot 11.

Next, the operation in which the robot 11 having the above configuration mounts the component 30 onto the substrate 40 (a method of controlling the component mounting device 10) is described with reference to FIGS. 3, 5a-5h, and 7-10. Note that, in FIGS. 5a-5h, in order to facilitate easier viewing of the figures, illustration of the pressing mechanism 55 (see FIG. 3) is omitted.

This operation is controlled by the control device 14. Note that one of the eight gripper parts 20 located at the inserting position is described. Since the operation is similar for other gripper parts 20, the description thereof is omitted.

Before mounting the substrate, a height measurement of the substrate 40 and a teaching of the robot 11 are performed.

### <Measurement of Height of Substrate>

This process is required when the substrate height H changes. Referring to FIG. 5a, the substrate 40 is placed on the placement part 24 (see FIG. 2), the component 30 is held by the holding body 52, and the pressing mechanism 55 (see FIG. 3) is made into a floating state (non-pressing state) in this state, while the tip ends of the insertion pins 31 of the component 30 are caused to contact the surface of the substrate 40, and the left end effector 19 is moved in the up-and-down direction, the height of the left end effector 19 (here, the position of the lower surface of the attachment member 50) is sensed when the holding body 52 is located at the center position of the second position range B. The movable body 51b of the slide mechanism 51 is then locked (R) to the stationary body 51a at this height. Then, a temporary substrate height H′ is calculated by subtracting the (known) height of the substrate 40 from the height of the left end effector 19. Further, a substrate height H is calculated by subtracting the length of the insertion pins 31 of the component 30 from the temporary substrate height H′. Note that, as the measurement location on the substrate 40, a location near the insertion holes 41a (see FIG. 3) which is an insertion target, where the insertion pins 31 are impossible to be inserted into the insertion holes 41a, is selected.

### <Teaching>

Next, in order to align the component with the insertion holes 41a, a target position of the left end effector 19 is taught. For example, in a state where the component 30 is held by the holding body 52 and the pressing mechanism 55 (see FIG. 3) is made into the floating state (non-pressing state), the insertion pins 31 of the component 30 are fully inserted into the insertion holes of the substrate 40, and the height of the left end effector 19 when the holding body 52 is located at the center position of the second position range B is sensed, while moving the left end effector 19 in the up-and-down direction. Then, the movable body 51b of the slide mechanism 51 is locked (R) to the stationary body 51a at this height. Then, the position of the left end effector 19 at this time is taught as the target position.

Subsequently, a holding operation and an inserting operation of the component are performed.

### <Holding Operation of Component>

As illustrated in FIG. 2, in front of the robot 11, a workbench 32 where the component(s) 30 is disposed, and a belt conveyor 33 onto which the substrate 40 is transferred are provided. Each component 30 on the workbench 32 is disposed so that the insertion pins 31 are oriented downwardly. The belt conveyor 33 extends in the left-and-right direction, and two substrates 40 disposed adjacently to each other in the front-and-rear direction are conveyed from the left to the right on the belt conveyor 33.

First, the robot 11 moves the left, end effector 19 so that the left end effector 19 contacts the left end of the substrate 40, and then moves the substrate 40 to the right side so that the substrate 40 is placed at a placement part 24 between the belt conveyors 33. The placement part 24 is located somewhat higher than the belt conveyor 33, and the substrate 40 placed on the placement part 24 stops at a location in front of the robot 11. The robot 11 moves the left arm part 15 to forward to move the holding body 52 to the workbench 32.

Referring to FIGS. 2 and 3, the robot 11 operates the gripper member actuator 53 of the gripper part 20 located at the inserting position, and causes the pair of gripper members 54 to pinch the component 30 on the workbench 32. Thus, the component 30 is held by the holding body 52.

Then, the holding body 52 is moved above another component, and the rotary part 21 is rotated so that another gripper part 20 is located. at the inserting position. Then, similarly, the gripper member actuator 53 of the gripper part 20 located at the inserting position is operated, and the component 30 on the workbench 32 is pinched by the pair of gripper members 54. This operation is repeated by a desired number of times.

### <Component Inserting Operation>

The robot 11 moves the left arm part 15 rearwardly to move the gripper part 20 and the component 30 gripped by this gripper part onto the substrate 40. Then, the component inserting operation is performed.

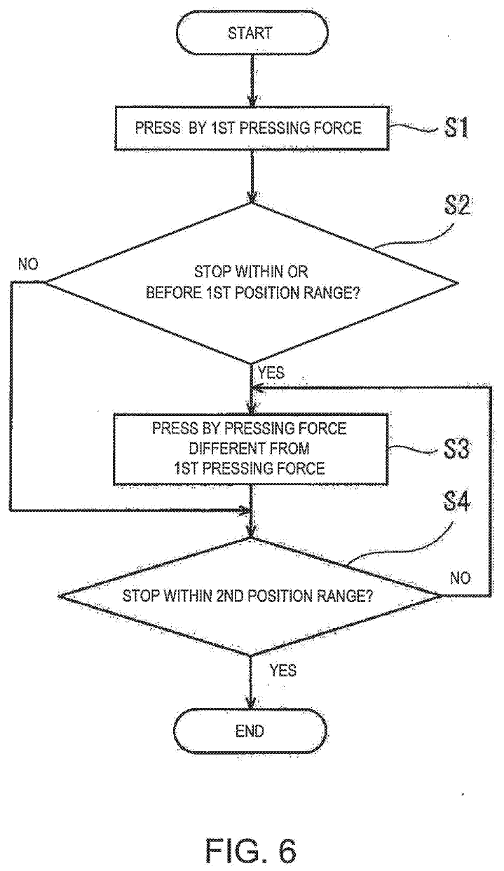

FIG. 6 is a flowchart illustrating an outline of one example of the component inserting operation executed by the control device 14 of the robot in FIG. 1. Here, it is described as operation of the robot 11.

The robot 11 causes the pressing mechanism 55 to press the holding body 52 located at the start position by a first pressing force (Step S1).

Subsequently, the robot 11 determines whether the holding body 52 is stopped within or before the first position range A (Step S2).

If the holding body 52 is not stopped (NO at Step S2), the robot 11 transits to Step S4.

If the holding body 52 stopped (YES at Step S2), the holding body 52 is pressed by a pressing force different from the first pressing force (Step S3).

Subsequently, the robot 11 determines whether the holding body 52 is stopped within the second position range B (Step S4).

If the holding body 52 is not stopped (NO at Step S4), the holding body 52 is pressed by a pressing force different from the first pressing force until the holding body 52 stops within the second position range B (Steps S3 and S4).

If the holding body 52 is stopped (YES at Step S4), the robot 11 determines that the component held by the holding body 52 is normally inserted into the insertion holes 40a of the substrate 40, and ends the inserting operation. Then, the gripper member actuator 53 of the gripper part 20 is operated to release the component 30 pinched by the pair of gripper members 54. Then, the robot 11 causes the pressing mechanism 55 to bring the holding body 5 back to the start position.

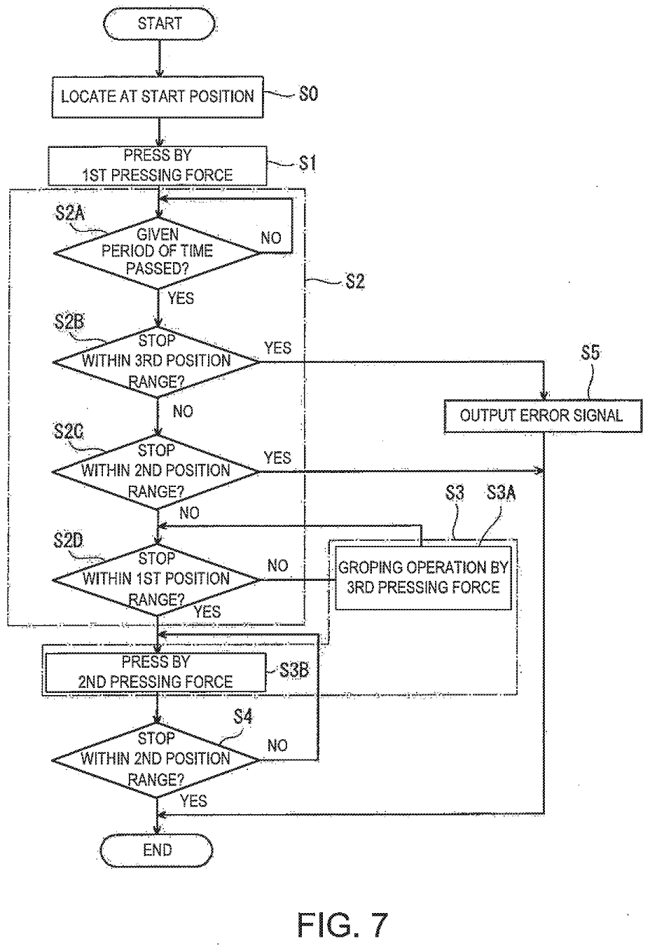

Next, a concrete example of this component inserting operation is described. FIG. 7 is a flowchart illustrating concrete processes of one example of the component inserting operation executed by the control device of the robot in FIG. 1.

Referring to FIGS. 5c-5h and 7, the robot 11 first retreats the piston rod 55b of the pressing mechanism 55 to locate the holding body 52 at the start position (Step S0).

Subsequently, the robot 11 deploys the piston rod 55b of the pressing mechanism 55 to press the holding body 52 located at the start position by the first pressing force (Step S1). Here, the first pressing force is set (selected) according to the component, and it is, for example, 3N to 5N.

Subsequently, the robot 11 stands by for a given period of time (Step S2A). This given period of tune is set a period of time which is sufficient for, for example, normally inserting the component 30 by the first pressing force.

When the given period of time passes, the robot 11 determines whether the holding body 52 is stopped within the third position range A (Step S2B).

If the holding body 52 is stopped (YES at Step S2B), since it is a case where the holding body 52 does not hold the component as illustrated in FIG. 5c, the robot 11 outputs an error signal (Step S5), and ends the inserting operation.

If the holding body 52 is not stopped (NO at Step S2B), the robot 11 determines whether the holding body 52 is stopped within the second position range B (Step S2C).

If the holding body 52 is stopped (YES at Step S2C), it is a case where the insertion pins 31 of the component 30 held by the holding body 52 are fully inserted, as illustrated in FIG. 5d. Such a case may include a case where, as illustrated in the first row of FIG. 10, the component 30 has the straight insertion pins 31 which are not deformed. In this case, the robot 11 determines that the component 30 is normally inserted into the insertion holes 40a of the substrate 40, and ends the inserting operation. Then, the gripper member actuator 53 of the gripper part 20 is operated to release the component 30 pinched by the pair of gripper members 54. Then, the pressing mechanism 55 brings the holding body 5 back to the start position.

If the holding body 52 is not stopped (NO at Step S2C), the robot 11 determines whether the holding body 52 is stopped within the first position range A (Step S2D).

If the holding body 52 is not stopped (NO at Step S2D), it is in the state where the tip ends of the pins 31 of component 30 contact the surface of the substrate 40, as illustrated in FIG. 5e. This state is produced by a positioning error of the component 30, a comparatively large deformation of the insertion pin(s) 31, etc. In this case, the robot 11 causes the groping mechanism to perform the groping operation of the holding body 52 (Step S3A), and then returns to Step S2D. The groping operation is performed by moving the component 30 held by the holding body 52 relatively to the substrate 40 in a direction parallel to the substrate 40 so as to grope or find out the insertion holes 40a of the substrate 40. This groping operation is performed, while pressing the holding body 52 by a third pressing force which is smaller than the first pressing force. The second pressing force may be, for example, 1 to 2.5 Nm. This pressing force can prevent the insertion pins 31 from being bent by the groping operation. The pair of gripper members 54 may be pinching or releasing the component 30. Here, the pair of gripper members 54 are set in a releasing state (see FIG. 5f).

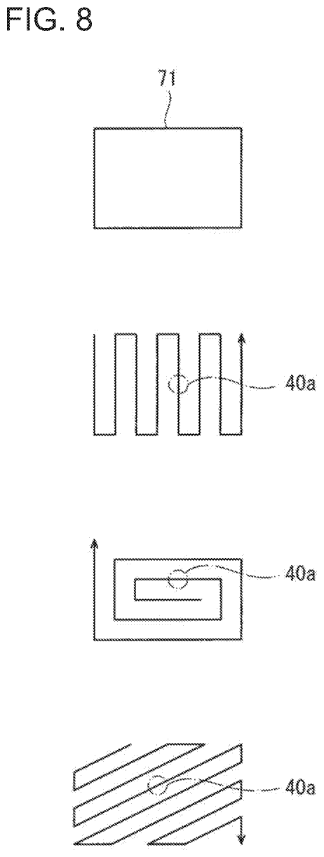

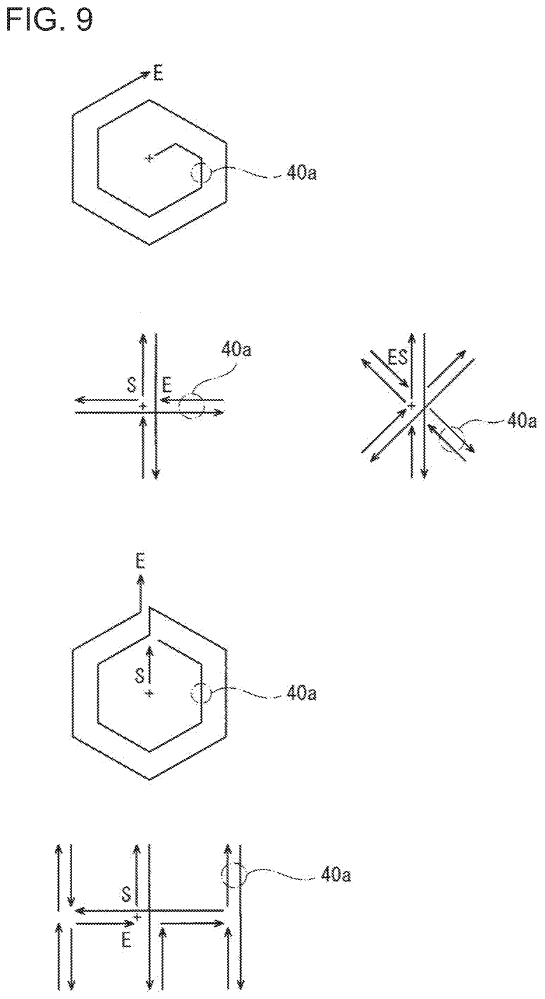

FIG. 8 is a schematic view illustrating loci of the holding body 52 during the groping operation. Referring to FIG. 8, the groping operation is performed by controlling the groping mechanism so that, for example, when seen in the pressing direction of the pressing mechanism 55, a locus of the holding body 52 draws one straight line which connects a plurality of parallel lines at a given interval within a given area 71 (see FIG. 8a).

FIG. 9 is a schematic view illustrating other loci of the holding body 52 during the groping operation. In FIG. 9, “+” indicates a starting point of the groping operation, and “S” and “E” indicate a start operation and an end operation, respectively.

In the first row of FIG. 9, a “spiral type” groping operation is illustrated. In this pattern of operation, the holding body 52 is moved so as to draw a polygonal spiral locus of the holding body 52. The number of sides of the polygon is three or more, and, here, a pattern of operation in the case of a hexagon shape is illustrated.

In the second row of FIG. 9, “radial type” groping operations are illustrated. In this pattern of operation, the holding body 52 is moved so that the locus of the holding body 52 is located along diagonal lines of the polygon. The number of sides of the polygon is three or more, and, here, the patterns of operation in the case of a square shape and a hexagon shape are illustrated. Moreover, the loci of the holding body 52 are intermittently formed. In this broken-off part, the holding body 52 is retreated by a suitable distance. Thus, as illustrated in FIG. 8, the groping operation may be a broken-off pattern of operation, without being limited to the pattern of operation drawn with a single stroke.

In the third row of FIG. 9, a “multiple type” groping operation is illustrated. In this pattern of operation, the holding body 52 is moved so that the locus of the holding body 52 draws multiple polygons. The number of sides of the polygon is three or more, and, here, the pattern of operation in the case of the hexagon shape is illustrated.

In the fourth row of FIG. 9, an “HH type” groping operation is illustrated. In this pattern of operation, the holding body 52 is moved so that the locus of the holding body 52 draws a shape of characters “HH” where the characters H are connected horizontally.

Summarizing the groping operations in FIGS. 8 and 9, the locus of the holding body 52 may be formed by drawing a plurality of parallel line groups within the given area 71, when seen in the pressing direction of the pressing mechanism 55. In other words, the groping mechanism may be controlled to move the holding body 52 so that hatching is drawn within the given area 71. Therefore, by suitably reducing the interval of the plurality of parallel lines, since the holding body 52 can be moved so as to perform a high-density scan of the given area 71 on the surface of the substrate 40, the tip ends of the insertion pins 31 of the component 30 can be inserted into the insertion holes 40a with high probability.

Note that, when performing the groping operation while the pair of gripper members 54 are in a pinching state, a locus of the component 30 will be similar to the locus of the holding body 52 illustrated in FIGS. 8 and 9. On the other hand, when performing the groping operation while the pair of gripper members 54 are in the releasing state, the locus of the component 30 draws a locus which randomly deviates from the locus of the holding body 52 illustrated in FIGS. 8 and 9. Thus, the probability of inserting the tip ends of the insertion pins 31 of the component 30 into the insertion holes 40a improves.

Here, the groping mechanism is the arm 13 of the robot 11.

Returning to FIG. 7, when the holding body 52 is stopped within the first position range A at Step S2D (YES at Step S2D), the insertion pins 31 of the component 30 are partially inserted into the insertion holes 40a of the substrate 40, as illustrated in FIG. 5g. This state may be caused, when the above-described groping operation is performed, and when the insertion pins 31 of the component 30 have the barb part(s) or the bending part(s) the second and fourth rows of FIG. 10). In this case, the robot 11 presses the holding body 52 by the second pressing force larger than the first pressing force (Step S3B). The second pressing force is suitably determined. according to the kind of component 30. Moreover, the state where the insertion pins 31 of the component 30 are partially inserted into the insertion. holes 40a of the substrate 40 may be caused when the hooks extending obliquely downward are formed in the tip-end parts of the insertion pins 31 of the component 30 (see the third row of FIG. 10). In this case, the robot 11 rotates the holding body 52 about the center axis of the component 30 while pressing the holding body 52 by the second pressing force larger than the first pressing force. This rotation is performed by suitably operating the left arm 13 of the robot 11.

Subsequently, the robot 11 determines whether the holding body 52 is stopped within the second position range B (Step S4).

If the holding body 52 is not stopped (NO at Step S4), the holding body 52 is pressed by the second pressing force until the holding body 52 stops within the second position range B (Steps S4 and S3B). Moreover, when the hooks extending obliquely downward are formed in the tip-end parts of the insertion pins 31 of the component 30, the rotating operation is continued.

If the holding body 52 is stopped (YES at Step S4), the robot 11 determines that the component 30 held by the holding body 52 is normally inserted into the insertion holes 40a of the substrate 40, as illustrated in FIG. 5h, and ends the inserting operation. Then, the gripper member actuator 53 of the gripper part 20 is operated to release the component 30 pinched by the pair of gripper members 54. Then, the pressing mechanism 55 brings the holding body 5 hack to the start position.

Then, after all the components 30 are inserted into the substrate 40, while rotating the rotary part 21, the right end effector 18 contacts the left end of the substrate 40 and moves the substrate 40 to the right side. Thus, the substrate 40 is moved to the belt conveyor 33 from the placement part 24, and the substrate 40 is conveyed on the belt conveyor 33.

As described above, according to Embodiment 1, in the state where the component 30 held by the holding body 52 may not be inserted normally, since the holding body 52 is stopped en route, and its handling operation is then performed, the inserting operation of the component 30 can be performed continuously.

### Embodiment 2

Embodiment 2 of the present disclosure illustrates a form provided with a servo motor (not illustrated) and a rotation linear motion conversion mechanism (illustrated) as the pressing mechanism 55, instead of the air cylinder of Embodiment 1, and provided with an encoder provided to an output shaft of the servo motor as the position detector 57, instead of the linear scale of Embodiment 1. Other configurations are similar to those of

Embodiment 1. Since the servo motor, the rotation linear motion conversion mechanism, and the encoder are well known in the art, they are described only briefly.

The rotation linear motion conversion mechanism is a mechanism which converts the rotation of the servo motor into a linear motion, and may be a rack and a pinion, a ball screw mechanism, etc.

According to Embodiment 2, the reciprocation of the holding body 52 can be controlled more precisely by the control device 14 carrying out the position control of the servo motor based on the rotational angle of the servo motor detected by the encoder. Note that the servo motor is also possible to make the pressing mechanism 55 in the floating state.

### Other Embodiments

In Embodiment 1 or 2, as the groping mechanism, the substrate 40 may be moved in a direction parallel to a principal surface of the substrate 40.

It is apparent for a person skilled in the art that many improvements and other embodiments of the present disclosure are possible from the above description. Therefore, the above description is to be interpreted only as illustration, and is provided in order to teach a person skilled in the art the best mode that implements the present disclosure. The details of the structures and/or the functions may be changed substantially, without departing from the spirit of the present disclosure.

### INDUSTRIAL APPLICABILITY

The present disclosure is useful for the component mounting device which can continuously perform the inserting operation of the component.

### DESCRIPTION OF REFERENCE CHARACTERS

10 Component Mounting Device

11 Robot

13 Arm

14 Control Device

18 Right End Effector

19 Left End Effector

20 Gripper Part

30 Component

31 Insertion Pin

40 Substrate

40a Insertion Hole

52 Holding Body

54 Gripper Member

55 Pressing Mechanism

57 Position Detector

A First Position Range

Second Position Range

Third Position Range

1. A component mounting device configured to insert an insertion pin of a component having the insertion pin into an insertion hole of a substrate and mount the component to the substrate, comprising:
a holding body configured to hold the component;
a pressing mechanism configured to press the holding body to move the holding body on a given route;
a position detector configured to detect a position of the holding body on the given route; and
a controller configured to control the pressing mechanism based on the position of the holding body detected by the position detector,
wherein, on the given route, a position of the holding body at which the insertion pin of the component held by the holding body is separated from the insertion hole of the substrate is a start position, a position range of the holding body at which the insertion pin of the component held by the holding body is partially inserted into the insertion hole of the substrate is a first position range, and a position of the holding body at which the insertion pin of the component held by the holding body is fully inserted into the insertion hole of the substrate is a second position range, and
wherein in a case where the holding body is pressed by a first pressing force to move on the given route from the start position toward the second position range, the controller controls the pressing mechanism to press the holding body by a pressing force different from the first pressing force, when the holding body stops at a position before or within the first position range.

2. The component mounting device of claim 1, wherein the controller controls the pressing mechanism to press the holding body by a second pressing force larger than the first pressing force, when the holding body stops within the first position range.

3. The component mounting device of claim 1, further comprising a groping mechanism configured to perform a groping operation in which the component held by the holding body is relatively moved with respect to the substrate in a direction parallel to the substrate so that the component gropes the insertion hole of the substrate,
wherein when the holding body stops before the first position range, the controller controls the groping mechanism to perform the groping operation, while controlling the pressing mechanism to press the holding body by a third pressing force smaller than the first pressing force.

4. The component mounting device of claim 3, wherein the controller controls the groping mechanism so that a locus of the holding body draws a plurality of parallel line groups within a given area, when seen in the pressing direction of the pressing mechanism.

5. The component mounting device of claim 1, wherein the position detector successively detects the position of the holding body on the given route.

6. The component mounting device of claim 1, wherein a position of the holding body at which the holding body that does not hold the component contacts the substrate is a third position range, and
wherein in a case where the holding body is pressed by the first pressing force to move on the given route from the start position toward the second position range, the controller outputs an error signal when the holding body stops within the third position range.

7. A method of controlling a component mounting device configured to insert an insertion pin of a component having the insertion pin into an insertion hole of a substrate and mount the component to the substrate,
wherein the component mounting device includes:
a pressing mechanism configured to press a holding body configured to hold the component to move the holding body on a given route;
a position detector configured to detect a position of the holding body on the given route; and
a controller configured to control the pressing mechanism based on the position of the holding body detected by the position detector,
wherein, on the given route, a position of the holding body at which the insertion pin of the component held by the holding body is separated from the insertion hole of the substrate is a start position, a position range of the holding body at which the insertion pin of the component held by the holding body is partially inserted into the insertion hole of the substrate is a first position range, and a position of the holding body at which the insertion pin of the component held by the holding body is fully inserted into the insertion hole of the substrate is a second position range, and
wherein in a case where the holding body is pressed by a first pressing force to move the holding body on the given route from the start position toward the second position range, the controller controls the pressing mechanism to press the holding body by a pressing force different from the first pressing force, when the holding body stops at a position before or within the first position range.
